(19) United States
(12) Patent Application Publication
(10) Pub. No.: US 2015/0069993 A1
(43) Pub. Date: Mar. 12, 2015

(54) APPARATUS FOR MONITORING AND DIAGNOSING POWER TRANSMISSION LINE

(71) Applicant: Hyundai Heavy Industries Co., Ltd., Ulsan (KR)

(72) Inventors: Beung Jin Kim, Seoul (KR); Hee Cheol Myoung, Seoul (KR); Deok Hwan Cho, Yongin (KR)

(21) Appl. No.: 14/483,407

(22) Filed: Sep. 11, 2014

(30) Foreign Application Priority Data
Sep. 12, 2013 (KR) 10-2013-0109809

(51) Int. Cl. G01R 21/133; G01R 21/00

(52) U.S. Cl. CPC G01R 21/133; G01R 21/00
USPC 324/76.11

(57) ABSTRACT

There is provided a power transmission line monitoring apparatus installed on a power transmission line to monitor a geomagnetically induced current (GIC) flowing along the power transmission line. The power transmission line monitoring apparatus includes: a main body installed on a power transmission line; a sensing unit embedded in the main body to sense a geomagnetically induced current flowing along the power transmission line; a data collecting and processing unit embedded in the main body and connected to the sensing unit to collect geomagnetically induced current data sensed by the sensing unit and process the collected geomagnetically induced current data; and a wireless communication modem embedded in the main body and connected to the data collecting and processing unit to transmit the data processed by the data collecting and processing unit to a remote data collecting device.

### CROSS-REFERENCE TO RELATED APPLICATION

This application claims the benefit of Korean Patent Application No. 10-2013-0109809 filed on Sep. 12, 2013, with the Korean Intellectual Property Office, the disclosure of which is incorporated herein by reference.

### BACKGROUND

The present disclosure relates to an apparatus for monitoring power transmission lines and, more particularly, to a power transmission line monitoring apparatus installed on power transmission lines to monitor geomagnetically induced currents (GIC) flowing in power transmission lines.

Space weather is defined as physical phenomena occurring in space, caused due to solar activity or cosmic radiation, for example, and which affects human activities in space and on the ground. Such phenomena have so far been reported to affect various fields, and among such phenomena is a space weather phenomenon affecting power grids.

Typical space weather phenomena include geomagnetic storms, solar flares, and radiation storms, for example, and, among these, geomagnetic storms have been known to affect power grids.

A phenomenon in which the strength of the earth's magnetic field is rapidly reduced due to solar activity is known as a geomagnetic storm or a geomagnetic disturbance (GMD). GMDs can cause geomagnetically induced currents to circulate in terrestrial power grids, resulting in power grid disturbances.

Thus, a technique of sensing an induced current flowing along power grids, in real time, is required.

### SUMMARY

An aspect of the present disclosure may provide a power transmission line monitoring apparatus capable of sensing a geomagnetically induced current (GIC) circulating in a power transmission line and providing corresponding information for a user.

According to an aspect of the present disclosure, a power transmission line monitoring apparatus may include: a main body installed on a power transmission line; a sensing unit embedded in the main body to sense a geomagnetically induced current flowing in the power transmission line; a data collecting and processing unit embedded in the main body and connected to the sensing unit to collect geomagnetically induced current data sensed by the sensing unit and process the collected geomagnetically induced current data; and a wireless communication modem embedded in the main body and connected to the data collecting and processing unit to transmit the data processed by the data collecting and processing unit to a remote data collecting device.

The data collecting and processing unit may be configured as a fast Fourier transform (FFT) device performing discrete Fourier transforms (DFT) on the data sensed by the sensing unit.

The wireless communication modem may be configured to transmit data using wireless mobile or Wi-Fi communication.

The main body may include an antenna for wireless mobile communications and an antenna for a Wi-Fi communication both connected to the wireless communication modem.

The sensing unit, the data collecting and processing unit and the wireless communication modem may be configured to harvest operating energy through a current flowing along the power transmission line on which the main body is installed.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic view illustrating a state in which a power transmission line monitoring apparatus is installed on a power transmission line according to an exemplary embodiment of the present disclosure;

FIG. 2 is a perspective view of the power transmission line monitoring apparatus of FIG. 1; and

FIG. 3 is a block diagram schematically illustrating components included in the power transmission line monitoring apparatus illustrated in FIG. 1.

### DETAILED DESCRIPTION

Hereinafter, the exemplary embodiments of the present disclosure will be described in detail with reference to the accompanying drawings.

The disclosure may, however, be exemplified in many different forms and should not be construed as being limited to the specific embodiments set forth herein.

Rather, these embodiments are embedded so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

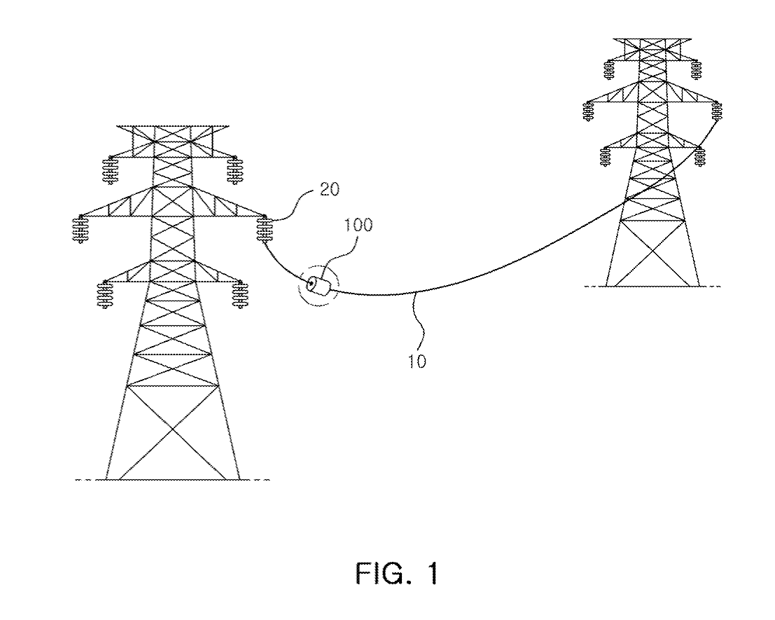

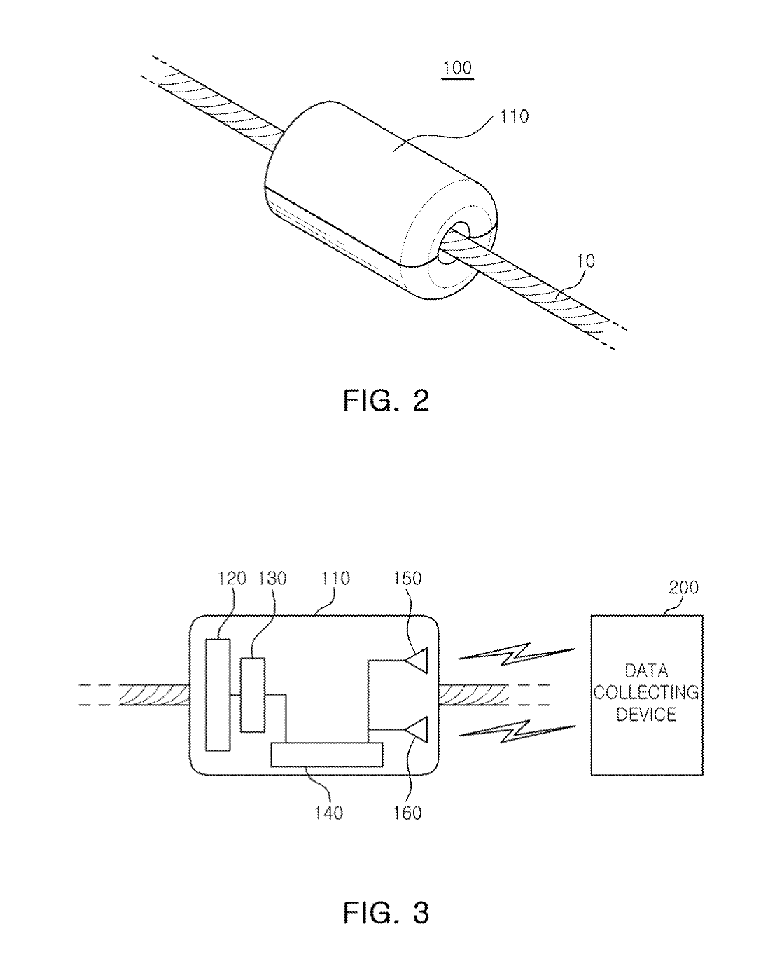

A power transmission line monitoring apparatus according to an exemplary embodiment of the present disclosure will be described with reference to FIGS. 1 through 3. FIG. 1 is a schematic view illustrating a state in which a power transmission line monitoring apparatus is installed on a power transmission line according to an exemplary embodiment of the present disclosure, FIG. 2 is a perspective view of the power transmission line monitoring apparatus of FIG. 1, and FIG. 3 is a block diagram schematically illustrating components included in the power transmission line monitoring apparatus illustrated in FIG. 1.

As illustrated in FIGS. 1 through 3, a power transmission line monitoring apparatus 100 according to an exemplary embodiment of the present disclosure includes a main body 110, a sensing unit 120, a data collecting and processing unit 130, and a wireless communication modem 140. The power transmission line monitoring apparatus 100 according to an exemplary embodiment of the present disclosure may further include an antenna 150 for wireless mobile communications and an antenna 160 for a Wi-Fi communication.

The main body 110 may form an outer casing of the power transmission line monitoring apparatus 100 according to an exemplary embodiment of the present disclosure and may be installed on a power transmission line 10.

In an exemplary embodiment, the main body 110 may be configured as a cylindrical structure installed on the power transmission line 10 such that the power transmission line 10 passes through a hollow thereof, but the present disclosure is not limited thereto.

Also, in an exemplary embodiment, the main body 110 may be installed on the power transmission line about 2 to 3 meters away from an insulator 20.

The sensing unit 120 may be embedded in the main body 110 and sense a geomagnetically induced current flowing along the power transmission line 10. The sensing unit 120 is not particularly limited and may be configured as a current sensor able to measure a magnitude of a current flowing along the power transmission line 10.

The data collecting and processing unit 130 is also embedded in the main body 110, like the sensing unit 120. The data collecting and processing unit 130 may be connected to the sensing unit 120 to collect geomagnetically induced current data sensed by the sensing unit 120 and process the same.

In an exemplary embodiment, the data collecting and processing unit 130 may process a magnitude of a geomagnetically induced current sensed by the sensing unit 120 each time the geomagnetically induced current is detected and record the same to create data with which a user may recognize points in time at which a geomagnetically induced current circulates in the power transmission line 10 and magnitudes of geomagnetically induced currents over time.

For example, the data collecting and processing unit 130 may be configured as a fast Fourier transform (FFT) device performing discrete Fourier transforms (DFT) on the data of a geomagnetically induced current sensed by the sensing unit 120.

In this manner, the data collecting and processing unit 130 configured as an FFT device may create a time-current magnitude graph by aligning magnitude data of geomagnetically induced currents sensed by the sensing unit 120 based on a time axis.

The wireless communication modem 140 may be embedded in the main body 110. The wireless communication modem 140 may be connected to the data collecting and processing unit 130 to transmit data processed by the data collecting and processing unit 130 to the remote data collecting device 200.

The remote data collecting device 200 may be configured as a terminal with which a user may check the data generated by the data collecting and processing unit 130.

The remote data collecting device 200 may analyze the data generated by the data collecting and processing unit 130 through a program to monitor the power transmission line 10 and determine a state of the power transmission line 10.

In addition, the remote data collecting device 200 may be disposed in or configured as a portable wireless terminal that may be carried by a user.

In an exemplary embodiment, the wireless communication modem 140 may be configured to transmit data using wireless mobile or Wi-Fi communication.

To this end, in an exemplary embodiment, the main body 110 may include the antenna 150 for wireless mobile communications and the antenna 160 for a Wi-Fi communication.

In the power transmission line monitoring apparatus 100 according to an exemplary embodiment of the present disclosure, the sensing unit 120, the data collecting and processing unit 130, and the wireless communication modem 140 may be configured to harvest operating energy through a current flowing along the power transmission line 10 in which the main body 110 is installed.

Namely, power for operating the sensing unit 120, the data collecting and processing unit 130, and the wireless communication modem 140 may be supplied from the power transmission line 10 on which the power transmission line monitoring apparatus 100 according to an exemplary embodiment of the present disclosure is installed.

The power transmission line monitoring apparatus 100 according to an exemplary embodiment of the present disclosure may sense, in real time, a geomagnetically induced current circulating in the power transmission line 10, caused due to geomagnetic disturbance, by means of the sensing unit 120 and provide data regarding the geomagnetically induced current for a remote user, thereby preventing malfunction of an electric power device and a power grid hindrance due to the geomagnet disturbance and creating data required for recognizing or detecting a cause of a power grid hindrance.

As set forth above, according to exemplary embodiments of the present disclosure, a geomagnetically induced current circulating in the power transmission line 10, caused due to geomagnetic disturbance, may be sensed, in real time, through the sensing unit and data regarding the geomagnetically induced current is embedded for a remote user, thereby preventing malfunction of an electric power device and a power grid hindrance due to the geomagnet disturbance and creating data required for recognizing or detecting a cause of a power grid hindrance.

While exemplary embodiments have been shown and described above, it will be apparent to those skilled in the art that modifications and variations could be made without departing from the spirit and scope of the present disclosure as defined by the appended claims.

What is claimed is:

1. A power transmission line monitoring apparatus comprising:
a main body installed on a power transmission line;
a sensing unit embedded in the main body to sense a geomagnetically induced current flowing along the power transmission line;
a data collecting and processing unit embedded in the main body and connected to the sensing unit to collect geomagnetically induced current data sensed by the sensing unit and process the collected geomagnetically induced current data; and wireless communication modem embedded in the main body and connected to the data collecting and processing unit to transmit the data processed by the data collecting and processing unit to a remote data collecting device.

2. The power transmission line monitoring apparatus of claim 1, wherein the data collecting and processing unit is configured as a fast Fourier transform (FFT) device performing discrete Fourier transforms (DFT) on the data sensed by the sensing unit.

3. The power transmission line monitoring apparatus of claim 1, wherein the wireless communication modem is configured to transmit data using wireless mobile or Wi-Fi communication.

4. The power transmission line monitoring apparatus of claim 3, wherein the main body comprises an antenna for wireless mobile communications and an antenna for a Wi-Fi communication both connected to the wireless communication modem.

5. The power transmission line monitoring apparatus of claim 1, wherein the sensing unit, the data collecting and processing unit, and the wireless communication modem are configured to harvest operating energy through a current flowing along the power transmission.
